(19) United States
(12) Patent Application Publication
(10) Pub. No.: US 2013/0259266 A1
(43) Pub. Date: Oct. 3, 2013

(54) ELECTRONIC DEVICE AND AUDIO PROCESSING CIRCUIT

(71) Applicants: Masatsugu Yayama, Osaka (JP); Hiroshi Oki, Osaka (JP)

(72) Inventors: Masatsugu Yayama, Osaka (JP); Hiroshi Oki, Osaka (JP)

(21) Appl. No.: 13/435,454

(22) Filed: Mar. 30, 2012

(51) Int. Cl. H03F 99/00

(52) U.S. Cl. 381/120

(57) ABSTRACT

A display device has an audio amplifier which amplifies and outputs an audio signal, and first and second isolation transformers which are provided in an electric power transmission path between a power source, which supplies electric power to the display device, and the audio amplifier.

### BACKGROUND OF THE INVENTION

1. Field of the Invention

The present invention relates to electronic devices, such as display devices, provided with an audio amplifier, and also relates to audio processing circuits provided with an audio amplifier.

2. Description of Related Art

A high degree of power isolation is often required in display devices provided with an audio amplifier and in audio processing circuits provided with an audio amplifier. Such requirement is supposed to be met, for example, in order to comply with UL 60065 Annex Q, the North American safety standard for hospitals.

It is, however, undesirable that achieving the high degree of power isolation results in deterioration in the frequency characteristics of an audio signal or a great increase in cost.

Unfortunately, technology which achieves a high degree of power isolation without deterioration in the frequency characteristics of an audio signal and without a great increase in cost in display devices provided with an audio amplifier and in audio processing circuits provided with an audio amplifier appears to be unavailable today.

### SUMMARY OF THE INVENTION

According to one aspect of the present invention, an electronic device is provided with: an audio amplifier which amplifies and outputs an audio signal; and first and second isolation transformers which are provided in the electric power transmission path between a power source, which supplies the electronic device with electric power, and the audio amplifier.

According to another aspect of the present invention, an audio processing circuit, is provided with: a voltage conversion circuit; an audio amplifier which amplifies and outputs an audio signal; an isolation transformer which is provided in the electric power transmission path between the voltage conversion circuit and the audio amplifier. Here, the voltage conversion circuit, the audio amplifier, and the isolation transformer are mounted on a single circuit board.

The significance and effect of the pre sent invention will be clearer from the following description of an embodiment of the invention. It should, however, be understood that the embodiment presented below is merely one example of how the invention can be implemented, and that the meanings of the terms used to describe the invention and its features are not limited to those in which they are used in the following description of the embodiment.

### BRIEF DESCRIPTION OF THE DRAWINGS

FIG. 1 is a front view of a television receiver according to one embodiment of the invention;

FIG. 2 is a schematic configuration diagram of the television receiver according to one embodiment of the invention; and

FIG. 3 is a configuration diagram illustrating power isolation according to the invention.

### DETAILED DESCRIPTION OF PREFERRED EMBODIMENTS

An embodiment of the present invention will be described below with reference to the accompanying drawings. The following description discusses, as an example of an electronic device according to the invention, a television receiver embodying the invention.

First, a set-up of a television receiver I according to one embodiment of the invention will be described.

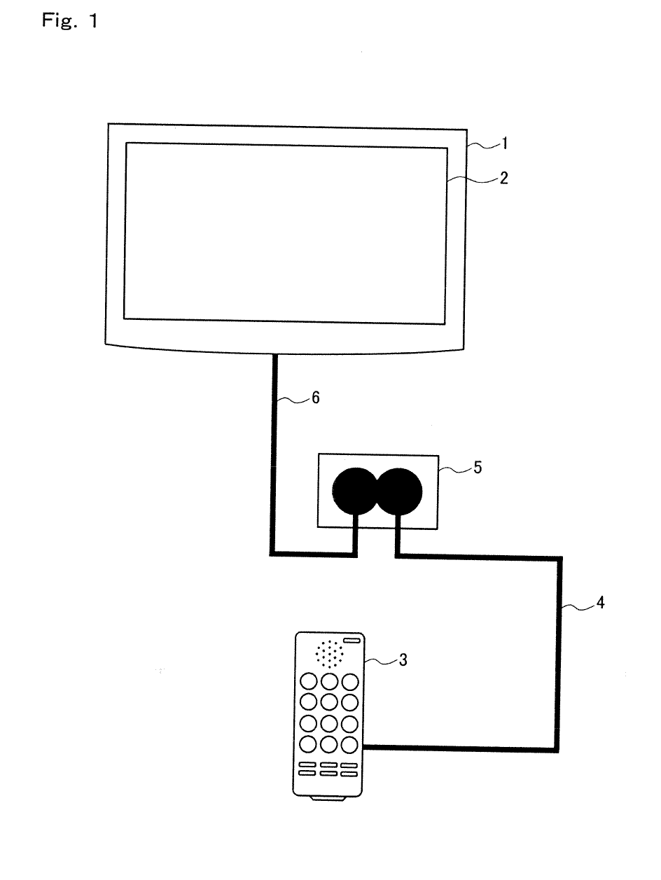

FIG. 1 is a front view of the television receiver 1. The television receiver 1 is a wall-hanging type television receiver, and is installed, for example, on a wall in a lobby, waiting room, patient's room, or the like in a hospital. On the front face of the television receiver 1, a display screen 2 is provided, and on the bottom face of the television receiver 1, a connector jack for a pillow speaker is provided.

In the set-up shown in FIG. 1, a general-purpose pillow speaker 3 is connected to the above-mentioned jack, via a cable 4, a wall socket 5 provided in a wall of a patient's room or the like, and a cable 6. Any different set-up is possible; for example, the general- purpose pillow speaker 3 may be connected directly to the above-mentioned jack by the cable, without relaying the wall socket 5.

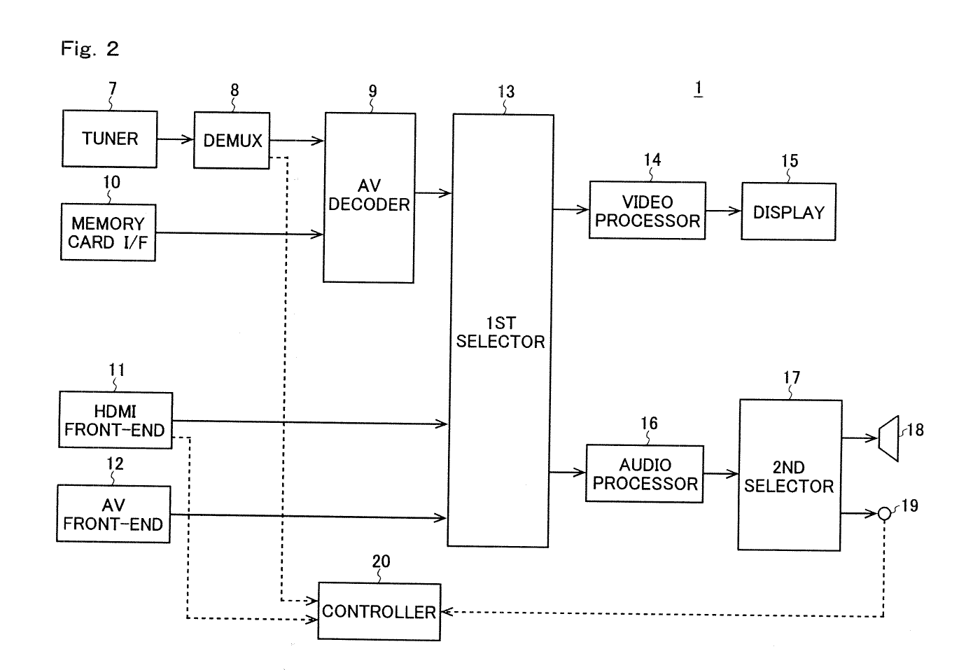

FIG. 2 is a schematic configuration diagram of the television receiver 1 embodying the present invention. The television receiver 1 is provided with a tuner 7, a demultiplexer (DEMUX) 8, an AV decoder 9, a memory card interface (I/F) 10, an HDMI (High-Definition Multimedia Interface) front-end 11, an AV front-end 12, a first selector 13, a video processor 14, a display 15 having the display screen 2 (see FIG. 1), an audio processor 16, a second selector 17, a built-in speaker 18, a pillow speaker connector jack 19, and a controller 20. In FIG. 2, for simplicity's sake, control signal lines for transmitting control signals from the controller 20 to relevant parts of the television receiver 1 are not illustrated.

The controller 20 outputs a channel select signal to the tuner 7 according to a signal transmitted from a remote control transmitter or the like. Based on the channel select signal, the tuner 7 selects a reception channel, then down-converts the radio-frequency signals corresponding to the reception channel, which is transmitted from a television broadcast reception antenna, to a signal having a specific frequency, then demodulates the specific frequency signal to generate a transport stream, and then outputs the produced transport stream to the demultiplexer 8.

The demultiplexer 8 separates the transport stream from the tuner 7 into a video stream, an audio stream, PSI/SI (program specific information/service information), etc., and then outputs the video and audio streams to the AV decoder 9 and the PSI/SI etc. to the controller 20.

The AV decoder 9 decodes the video and audio streams (A/V streams), and outputs the decoded signals to the first selector 13. Instead, the AV decoder 9 may decode A/V streams read from a memory card, such as an SD (Secure Digital) card, by the memory card interface 10.

The HDMI front-end 11 receives a video signal and an audio signal from an external device, such as an optical disc recording/playback device, STB (set-top box), or the like, via a TMDS (Transition Minimized Differential Signaling) data signal line of an HDMI cable, and outputs the received signals to the first selector 13.

The AV front-end 12 has a composite-video connector and a component-video connector; and receives a video signal and an audio signal from an external device such as an optical disc recording/playback device, STB, or the like, via a composite-video cable or a component-video cable, and outputs the received signal to the first selector 13. The AV front-end 12 may have a PC input connector (D-sub 15-pin) or an RS-232C connector for communicating control signals.

The first selector 13 selects the video and audio signals inputted from the AV decoder 9, the HDMI front-end 11, or the AV front-end 12, and outputs the selected video signal to the video processor 14 and outputs the selected audio signal to the audio processor 16.

The video processor 14 performs processing regarding to image quality or image size to the video signal outputted from the first selector 13.

The audio processor 16 performs processing regarding to sound quality and sound volume to the audio signal outputted from the first selector 13, and then outputs the processed audio signal to the second selector 17.

The second selector 17 selects either one of the built-in speaker 18 or the pillow speaker connector jack 19 according to an instruction from the controller 20, and outputs the audio signal outputted from the audio processor 16 to the selected one. The controller 20 monitors constantly whether or not the general-purpose pillow speaker 3 (see FIG. 1) is connected to the pillow speaker connector jack 19. When the speaker 3 is connected to the jack 19, the controller 20 instructs the second selector 17 to select the jack 19. When the speaker 3 is not connected to the jack 19, the controller 20 instructs the selector 17 to select the built-in speaker 18. Accordingly, when the general-purpose pillow speaker 3 is connected to the television receiver 1, the speaker 3 reproduces sound based on the audio signal outputted from the audio processor 16; when the speaker 3 is not connected to the television receiver 1, the built-in speaker 18 reproduces sound based on the audio signal outputted from the audio processor 16.

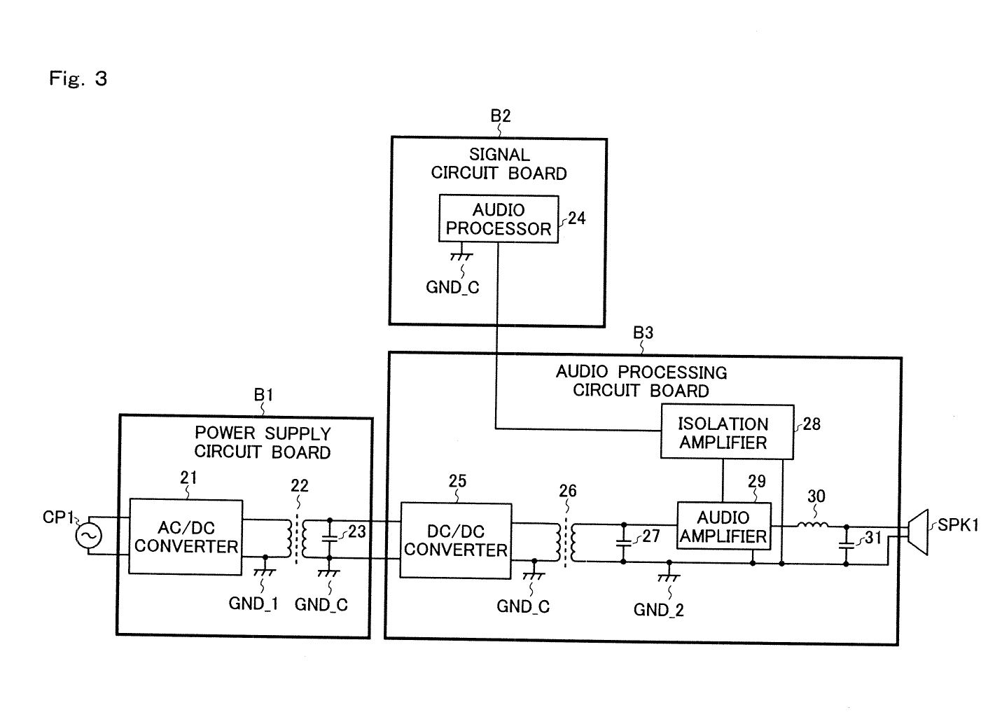

FIG. 3 is a configuration diagram regarding to power isolation according to the present invention.

A power supply circuit board B1 mounts a power supply circuit which supplies electric power to relevant parts of the television receiver 1; specifically the board B1 mounts an AC/DC converter 21, an isolation transformer 22, a capacitor 23, etc.

A signal circuit board B2, which is so called a main board mounts an audio processor 24 which performs signal processing to an audio signal. Further, on the board B2, the components shown in FIG. 2 (the tuner 7, demultiplexer 8, AV decoder 9, interface 10, front-ends 11 and 12, selectors 13, 17, processors 14 and 16, and controller 20) are mounted for example.

On an audio processing circuit board B3 a DC/DC converter 25, an isolation transformer 26, a capacitor 27, an isolation amplifier 28, an audio amplifier 29, and a smoothing circuit composed of an inductor 30 and a capacitor 31 are mounted.

The audio processor 24, the isolation amplifier 28, the audio amplifier 29, and the smoothing circuit (configured by the inductor 30 and the capacitor 31) are included in the audio processor 16 (see FIG. 2).

As shown in FIG. 3, the primary winding of the isolation transformer 22 is connected to a first floating ground (GND_1) which is formed in a predetermined region on the power supply circuit board B1. The secondary winding of the isolation transformer 22, the audio processor 24, and the primary winding of the isolation transformer 26 are connected to a common ground (GND_C) which is used as a common basis in the entire television receiver 1. For example, the ground line provided in outlets or plugs for commercial electric power may be utilized as GND_C. The secondary winding of the isolation transformer 26, the capacitor 27, the isolation amplifier 28, the audio amplifier 29, and the capacitor 31 are connected to a second floating ground (GND_2) which is formed in a predetermined region on the audio processing circuit board B3.

The AC/DC converter 21 rectifies an AC voltage supplied from a commercial electric power source CP1 with a diode bridge.

The rectified voltage is supplied to the primary winding of the isolation transformer 22 from the AC/DC converter 21. This induces a voltage commensurate with the voltage supplied to the primary winding of the isolation transformer 22 and winding factor of the isolation transformer 22 in the secondary winding of the isolation transformer 22. In the stage succeeding the isolation transformer 22, the capacitor 23 which converts the output from the secondary winding of the isolation transformer 22 into a DC voltage is provided.

The DC/DC converter 25 is a voltage conversion circuit which converts the DC voltage (first DC voltage) smoothed by the capacitor 23 into a switched pulse-wave voltage.

The pulse-wave voltage is supplied to the primary winding of the isolation transformer 26. This induces a pulse-wave voltage which is commensurate with the voltage supplied to the primary winding of the isolation transformer 26 and winding factor of the isolation transformer 26 in the secondary winding of the isolation transformer 26.

The pulse-wave voltage outputted from the secondary winding of the isolation transformer 26 is converted into a DC voltage by the capacitor 27, and this DC voltage is then supplied to the audio amplifier 29 as a supply voltage.

The audio processor 24 outputs the GND_C based audio signal, in which a predetermined signal processing is undergone, to the isolation amplifier 28. The isolation amplifier 28 converts the ground reference of the audio signal transmitted from the audio processor 24 from GND_C to GND_2 by isolation, and then outputs the GND_2 based audio signal to the audio amplifier 29.

The audio amplifier 29 power-amplifies the GND_2 based audio signal transmitted from the isolation amplifier 28 by using a GND_2 based DC voltage supplied from the capacitor 27, and then outputs the power-amplified audio signal.

By providing the isolation amplifier 28, the ground reference between the audio signal and the supply voltage that are inputted to the audio amplifier 29 can be unified as described above. Thus, it is possible to prevent disturbance in the waveform of the audio output signal due to difference in the ground reference between the audio signal and the supply voltage.

In the present embodiment, the audio amplifier 29 performs class-D amplification, and the output signal from the audio amplifier 29 is smoothed by the smoothing circuit configured by the inductor 30 and the capacitor 31, and then is transmitted to a speaker SPKI. The speaker SPK1 corresponds to the general-purpose pillow speaker 3 (see FIG. 1).

According to the above-described configuration of FIG. 3, since the commercial electric power source CP1 and the speaker SPK1 are isolated from each other doubly by the isolation transformers 22 and 26, it is possible to achieve a high degree of power isolation.

The double power isolation by the isolation transformers 22 and 26 may also be achieved, for example, by providing the isolation transformer 26 between the audio amplifier 29 and the speaker SPKI, instead of between the DC/DC converter 25 and the audio amplifier 29. However, when the isolation transformer 26 is provided between the audio amplifier 29 and the speaker SPKI, although the isolation amplifier 28 can be omitted, the frequency characteristics of the audio signal are unfavorably affected by the isolation transformer 26. To prevent this deterioration in the frequency characteristics of the audio signal, a transformer having good frequency characteristics, that is, an extremely expensive transformer (which is much expensive than the isolation amplifier 28) may be necessary. This incurs a great increase in cost.

By contrast, in the present embodiment, since the isolation transformer 26 is not provided between the audio amplifier 29 and the speaker SPK1, the frequency characteristics of the audio signal is ruled by the smoothing circuit configured by the inductor 30 and the capacitor 31. That is, the isolation transformer 26 does not unfavorably affect the frequency characteristics of the audio signal. Thereby, it is possible to use a low-cost transformer for the isolation transformer 26. Accordingly, the above described embodiment achieves a high degree of power isolation without deteriorating the frequency characteristics of the audio signal and without a great increase in cost.

The embodiment by way of which the present invention has been specifically described above is in no way meant to limit the scope of the invention; in implementing the invention, many modifications and variations are possible without departing from the spirit of the invention.

For example, in the embodiment described above is an example where present invention is applied to a television receiver. However, scope of the invention may be applied to the other type of display device (such as a television monitor without a tuner). Further, the invention may be applied to other electronic devices.

When a DC power source is used instead of the commercial electric power source CP1 which provides an AC voltage, the AC/DC converter 21 can be replaced with a DC/DC converter.

The present invention may be applied to a television receiver having a network interface for receiving content streams distributed across a network such as the Internet. In such case the AV decoder may be configured to decode those streams.

What is claimed is:

1. An electronic device, comprising:
an audio amplifier which amplifies and outputs an audio signal; and
first and second isolation transformers which are provided in an electric power transmission path between a power source and the audio amplifier, the power source supplying the electronic device with electric power.

2. The device according to claim 1, further comprising:
an isolation amplifier which converts, a ground reference of the received audio signal from a first ground to a second ground by isolation, and transmits the audio signal, in which the ground reference is converted to the second ground, to the audio amplifier, wherein
the second ground is a ground reference of a supply voltage supplied from the electric power transmission path to the audio amplifier is.

3. The device according to claim 1, further comprising:
a first circuit board comprising, mounted thereon,
an input section to which an external supply voltage is inputted,
a converter which converts the supply voltage inputted from the input section, and
the first isolation transformer; and
a second circuit board comprising, mounted thereon,
the audio amplifier; and
the second isolation transformer.

4. The device according to claim 3, further comprising:
an isolation amplifier which converts, a ground reference of the received audio signal from a first ground to a second ground by isolation, and transmits the audio signal in which
the ground reference is converted to the second ground to the audio amplifier, wherein the second ground is a ground reference of a supply voltage supplied from the electric power transmission path to the audio amplifier,
the first ground is a common ground used on a common basis in the entire electronic device, and
the second ground is a floating ground formed in a predetermined region on the second circuit board.

5. The device according to claim 1, further comprising a smoothing circuit which is provided in a stage succeeding the audio amplifier.

6. An audio processing circuit, comprising:
a voltage conversion circuit;
an audio amplifier which amplifies and outputs an audio signal, and
an isolation transformer which is provided in an electric power transmission path between the voltage conversion circuit and the audio amplifier, wherein
the voltage conversion circuit, the audio amplifier, and the isolation transformer are mounted on a single circuit board.
